(19) United States
(12) Patent Application Publication
(10) Pub. No.: US 2013/0147340 A1
(43) Pub. Date: Jun. 13, 2013

(54) DEVICE FOR PROVIDING A FLOW OF PLASMA

(71) Applicant: Thomas Bickford Holbeche, Church Crookham (GB)

(72) Inventor: Thomas Bickford Holbeche, Church Crookham (GB)

(21) Appl. No.: 13/495,521

(22) Filed: Jun. 13, 2012

(30) Foreign Application Priority Data
Jun. 17, 2011 (GB) 1110282.9

(51) Int. Cl. H01J 37/32

(52) U.S. Cl. CPC H01J 37/32009
USPC 313/231.31

(57) ABSTRACT

A device for forming at an ambient atmospheric pressure a gaseous plasma comprising active species for treatment of a treatment region. The device comprises a plasma cell for forming the gaseous plasma for treating the treatment region. The plasma cell comprises an inlet for receiving gas from a source and an outlet for discharging active species generated in the cell. A dielectric substrate made of a polyimide encloses the flow path for gas conveyed from the inlet to the outlet and an electrode is formed on the dielectric substrate for energising gas along the flow path to form the active species. A protective coating or lining is located on an inner surface of the dielectric substrate for resisting reaction of the active species generated in the plasma cell with the material of the dielectric substrate.

### FIELD OF THE INVENTION

The present invention relates to a device for providing a flow of atmospheric plasma. In particular the invention relates to a plasma cell of such a device.

### BACKGROUND OF THE INVENTION

Systems for the generation of non-thermal gas plasma are known and have utility in a number of fields such as industrial, dental, medical, cosmetic and veterinary fields for the treatment of the human or animal body. Non-thermal gas plasma generation can be employed to promote coagulation of blood, cleaning, sterilisation and removal of contaminants from a surface, disinfection, reconnection of tissue and treatment of tissue disorders without causing significant thermal tissue damage. In order to be tolerable for a patient, the atmospheric plasma flow, including ions and non-ionised gas, should be maintained at an acceptable temperature, preferably below about 40° C.

In such plasma devices, it is additionally desirable to conserve power and to increase the amount of active species (e.g. OH radicals) in the plasma which is delivered to the treatment region whilst also conserving gas consumption.

### SUMMARY OF THE INVENTION

It is an aim of the present invention to provide an improved plasma cell in a plasma delivery device.

The present invention provides a device for forming at an ambient atmospheric pressure a gaseous plasma comprising active species for treatment of a treatment region, the device comprising a plasma cell for forming said gaseous plasma for treating the treatment region, the plasma cell comprising an inlet for receiving gas from a source and an outlet for discharging active species generated in the cell, a dielectric substrate made of a polyimide enclosed around a flow path for gas conveyed from the inlet to the outlet and an electrode formed on the dielectric substrate for energising gas along the flow path to form active species, wherein a protective coating made of a dielectric is formed on an inner surface of the dielectric substrate for protecting the dielectric substrate from reaction with the active species.

The protective coating may be made of a material selected from one of PTFE, FEP or silicone rubber being generally un-reactive with the active species.

The electrode may be formed by patterning an electrically conductive material on the dielectric substrate.

In this regard, the electrode may be printed or may be formed of a fibrous matrix transferred onto the dielectric substrate.

The dielectric substrate is preferably flexible and shaped to define the flow path. The dielectric substrate may be formed by a flexible tube enclosing the flow path.

A protective sheath made of a dielectric may be formed around the dielectric substrate and electrode.

The device may comprise a plasma cell array having a plurality of said plasma cells.

The present invention also provides a plasma cell for such devices.

A device according to the invention may be made by forming an electrode onto a dielectric substrate made of a polyimide, configuring the dielectric substrate to form a flow path for gas from a cell inlet to a cell outlet and forming a protective dielectric coating on an inner surface of the dielectric substrate for protecting the substrate from reaction with the active species.

The electrode may be patterned onto the dielectric substrate.

The patterned electrode may be deposited on the dielectric substrate by printing or formed of a fibrous matrix transferred onto the dielectric substrate.

The dielectric substrate is flexible and following formation of the electrode on the substrate the substrate is shaped to enclose the flow path between the inlet and the outlet.

The dielectric substrate may be shaped to correspond with the shape of a former inside the device.

The protective coating may be made of a material which is generally unreactive with the active species generated in the cell.

The method may comprise forming a protective sheath made of a dielectric around the dielectric substrate and patterned electrode.

### BRIEF DESCRIPTION OF THE DRAWINGS

In order that the invention may be more clearly understood, several embodiments thereof, which are given by way of example only, will now be described in more detail with reference to the accompanying drawings, in which;

FIG. 1 shows a device for forming a plasma;

FIG. 2 shows a plasma cell of the device in more detail;

FIG. 3 shows in FIG. 3a a plasma cell in perspective, in FIG. 3b the plasma cell in longitudinal section, in FIG. 3c in lateral section, and in FIG. 4 the electrodes of the cell;

FIG. 4 shows in FIG. 4a a plasma cell in perspective, in FIG. 4b the plasma cell in longitudinal section, in FIG. 4c in lateral section, and in FIG. 4 the plasma cell in plan;

FIG. 5 shows a plasma cell in partial cut-away; and

FIG. 6 shows a device having a plasma cell array.

### DETAILED DESCRIPTION OF ILLUSTRATED EMBODIMENTS

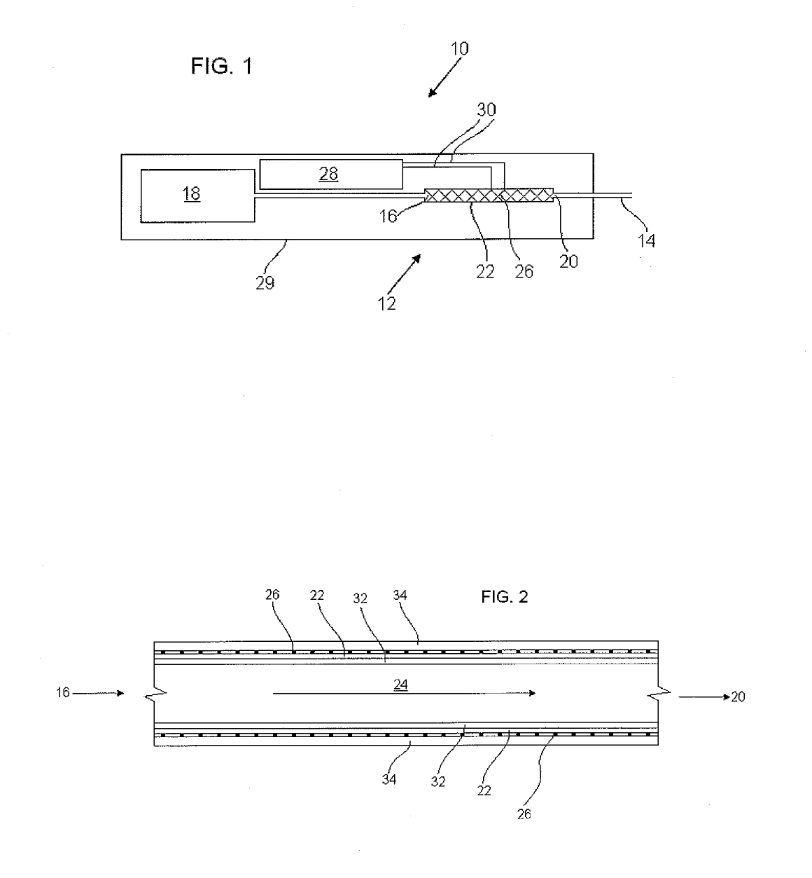

Referring to FIG. 1, there is shown a device 10 for providing a flow of plasma for treatment of a treatment region, which may be part of a human or animal body such as teeth. The device comprises a plasma cell 12 for forming at an ambient atmospheric pressure a gaseous plasma comprising active species to be discharged through nozzle 14 for treating the treatment region. The pressure need not be controlled to maintain strict ambient atmospheric pressure but significant positive or negative pressure should generally be avoided in the example of FIG. 1.

The plasma cell 12 comprises an inlet 16 for receiving gas from a source 18 and an outlet 20 for discharging active species generated in the cell. A dielectric substrate 22 is enclosed around a flow path 24 for gas conveyed from the inlet to the outlet. An electrode 26 is formed on an outer surface of the dielectric substrate and connected to a source of electrical power 28 by electrical connectors 30 for energising gas along the flow path to form active species. The electrode 26 may be embedded in the substrate or sandwiched between substrates. The source of electrical power is designed to drive the electrodes with a suitably high voltage and frequency to energise gas in the cell, for example 2.5 kV RMS at 100 MHz, however the voltage must not exceed the dielectric strength of the dielectric substrate to avoid conductive pathways being formed through the substrate. The source should also be configured not to overload the electrode configuration causing melting and consequent short circuiting of tracts of a patterned electrode configuration. A housing 29 houses the components of the device.

An enlarged section Il taken through the plasma cell is shown in FIG. 2. The electrode 26 in this example takes the form of a spiral and is transferred onto the outer surface of the generally cylindrical dielectric substrate 22. The electrode has a regular pattern to produce a generally uniform electric field in the plasma cell. A protective lining 32 is located on an inner surface of the dielectric substrate for resisting reaction of the active species generated in the cell 12 with the dielectric substrate 22. Such reaction if allowed would degrade the dielectric substrate and reduce its electrically insulating properties, or dielectric strength, and result in electrical conduction between the electrode and the gas in the cell. Such conduction may lead to arcing which heats the plasma, drains power and can produce undesirable active species. A protective sheath 34 surrounds the electrode and the dielectric substrate and protects the inner cell components from physical damage. The sheath in this example is made of a dielectric which protects the region external to the plasma cell from exposure to high voltage. The region external to the plasma cell typically contains air, and the high voltage would, if not protected by the sheath, produce ozone by energising oxygen in the air.

The protection provided by the protective lining means that the choice of materials for the dielectric substrate is larger than would be the case in the absence of the protective lining. In the latter case, the substrate would be required to be unreactive with the active species generated in the cell in addition to its required electrical properties. The active species are dependent upon the source gas from which the plasma is generated and may be argon or nitrogen. Accordingly, the substrate may be made of polyimide which has suitable electrical properties but is generally reactive with active species. The protective lining may be made of a material such as PTFE, FEP or silicone rubber being generally un-reactive with the active species. The composite structure of the cell provides an arrangement which has the required electrical properties but will not significantly degrade during use.

The dielectric substrate may be made of any suitable dielectric medium and is preferably thin having a thickness of less than 5 mm, preferably less than 2 mm and more preferably less than 1 mm. Since the electric field generated across the discharge gas in the cell is reduced by increasing thickness, a thin substrate allows a higher strength field to be generated with reduced power consumption. However, it will be noted that many dielectric mediums have insufficient strength particularly when thin to resist breaking down when exposed to an electric field which is sufficiently high to generate an atmospheric plasma in the chamber. Accordingly, the dielectric strength of the selected dielectric substrate should be sufficient to resist significant electrical conduction from the electrode to the gas in the cell. The dielectric material may be polyimide which has good electrical properties and is a flexible material meaning that it can be configured into any one of a number of different shapes, as will be described in more detail below.

Polyimides are polymers of imide monomers. Polyimides are lightweight, flexible, resistant to heat and chemicals, have a high dielectric strength and are able to act as a substrate for printed electrical components. Suitable polyimides for use in the invention and their preparation are described in, for example, U.S. Pat. No. 3,179,634. A well known procedure for preparing polyimides is the two step poly(amic acid) process which involves reacting a dianhydride and a diamine at ambient conditions in a dipolar aprotic solvent such as N,N-dimethylacetamide (DMAc) or N-methylpyrrolidone (NMP) to yield the corresponding poly(amic) acid. This acid is then cyclised into the final polyimide. Such polyimides are sold commercially, notably under the trade mark KAPTON. The polyimide used most extensively in KAPTON products is believed to utilise the monomer pyromellitic dianhydride and 4,4′-oxydianiline.

Some commercial polyimide products are laminates with other plastics materials. Such laminates are disclosed in U.S. Pat. No. 3,616,177 and US 2005/0013988 A1. The latter document specifically relates to dielectric substrates comprising a polyimide core layer and a high temperature fluoropolymer bonding layer.

It is also known to compound a polyimide with graphite or glass fibre so as to enhance its flexural strength and with metal so as to enhance its thermal conductivity. It is further known to provide grades of polyimide that are resistant to electrical corona discharge. For example, such products are commercially available as KAPTON CR and KAPTON FCR. Corona discharge-resistant forms of polyimide are known from, for example, U.S. Pat. No. 3,389,111. The compositions disclosed therein contain certain organo-metallic compounds, particularly aromatic, aliphatic or araliphatic compounds of elements selected from Groups IVb and Vb of the Periodic Table of elements and iron, in which the metal is bonded through carbon to the organic portion of the molecule.

Another suitable polyimide is APICAL polyimide film which is an AF type aromatic polyimide made by Kaneka Texas Corporation. This polyimide has a dielectric strength in a range of 118 to 197 kV/mm depending on the particular film selected.

The electrodes may be made from copper and printed onto the dielectric substrate by techniques used in the fabrication of printed circuit boards, such as deposition or etching. However, the electrode pattern is configured to generate a high electric field in the plasma cell, whereas in PCBs, a high electric field is generally undesirable. Further in PCBs, the wiring is formed on one side of a substrate and acts as electrical conductors predominantly used for carrying electrical signals between components located on the other side of the substrate by interconnecting vias. In the present invention, the electrode pattern does not carry signals and is designed for use with high electrical potentials of for example 1 kV (or much greater).

The protective sheath constitutes a physical barrier between the electrode pattern and substrate on the one hand and ambient conditions in the device and also provides structural support maintaining the cell in a generally cylindrical or other desired configuration. Accordingly, the protective sheath may be made of a thermoplastic such as polyether block amide. The protective sheath is also preferably a dielectric providing an electrical insulation between the electrode and the exterior of the plasma cell. Alternatively, a dielectric layer may overlay the dielectric substrate and electrode and one or more other layers may overlay the dielectric layer.

Additional layers may be provided in the laminated plasma cell, such as one or more adhesive layers, one or more additional electrode patterns, or one or more dielectric layers.

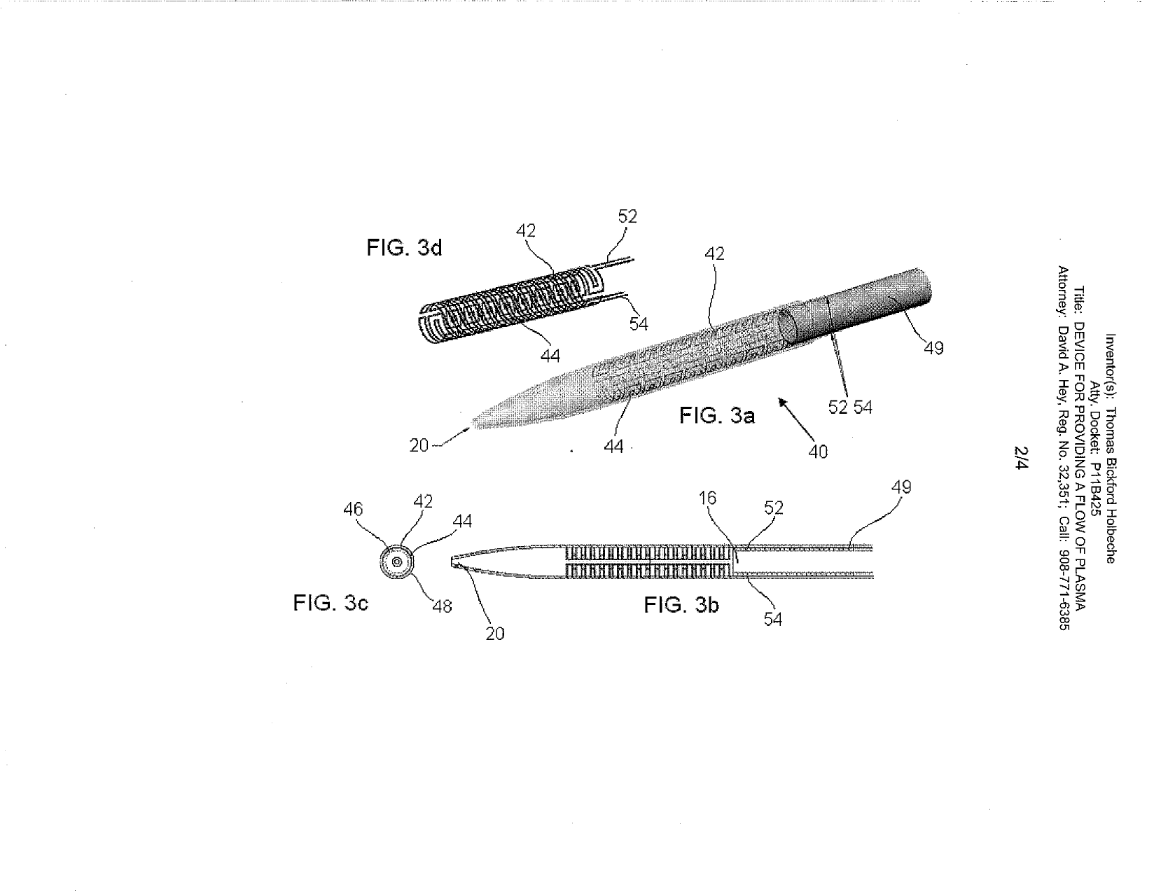

Referring to FIG. 3, a plasma cell 40 is shown in more detail in which the or each electrode is transferred to the dielectric substrate by printing, such as by deposition or etching. Like reference numerals will be used to denote like features discussed above and will not be explained again for brevity. The cell 40 comprises first electrode 42 and second electrode 44 both printed on a dielectric substrate 46 by printing techniques known in the fabrication of PCBs. A second dielectric layer 48 covers the patterned electrodes and protects and electrically insulates the cell. A gas conduit 49 conveys gas from a source of gas to the plasma cell. A protective lining is not shown in FIG. 3 for simplicity of the drawings.

In a preferred method of manufacture of the plasma cell, the electrode(s) 42, 44 are printed on a generally planar dielectric substrate such as polyimide which is flexible so that after printing the substrate can be formed into a desired configuration, which in this example is a cylinder with a tapering front portion forming the cell outlet 20. The generally rectangular planar substrate is formed into a cylinder and then longitudinal sides of the substrate are joined and fixed to secure the substrate in a cylindrical configuration. In this regard, printing of the electrode(s) on a planar substrate is more readily and inexpensively achieved than by printing on a cylindrical substrate and standard PCB manufacturing equipment is available for printing on planar substrates. Of course though, the present invention does not preclude printing or otherwise patterning the electrode on a cylindrical substrate.

Flexible electronic circuits, or so-called flex circuits, are known in other technical fields and are used in for example cameras and cell phones. In such fields electronic components are mounted on flexible plastic substrates, such as polyimide, PEEK or transparent conductive polyester film. Additionally, flex circuits can be screen printed silver circuits on polyester. These flexible printed circuits (FPCs) are typically made by photolithography. An alternative way of making flexible foil circuits is laminating very thin (e.g. 0.07 mm) copper strips in between two layers of PET. These PET layers, typically 0.05 mm thick, are coated with an adhesive which is thermosetting, and will be activated during the lamination process. These techniques may be used in the production of the present plasma cell. It will be noted however that the electrode arrangement of the present plasma cell is designed to carry high voltages (e.g. 1 to 3 kV) and high frequencies (e.g. above 100 kHz), whereas known flexible circuit boards are designed to carry low potentials at low frequencies.

The flexibility of the dielectric substrate means that it can be shaped to correspond with a former inside the device. The former may for example be a quartz tube or part of the nozzle attachment. This substrate flexibility allows more scope for positioning the plasma cell within the device leading to more efficient use of space and contributing to a reduction in size of the device or if preferred to an allowable increase of size of other components within the device such as the power source.

In the example shown in FIG. 3, two electrodes are shown and are connected to the source of electrical power by electrical connectors 52, 54. The connectors and the electrode patterns can be seen most clearly in FIG. 3d, in which other components of the cell have been removed. The pattern is configured to enhance the generation of active species in the cell and may consist of any suitable shapes such as coils, zigzags or curvilinear tracks. Printing the pattern enables complex and suitable patterns to be produced without significant expense and without the risk of short-circuiting between tracks. Preferably the pattern covers as much of the surface of the cell as possible so that a generally uniform electric field is applied to gas in the cell. The patterns may be formed without abrupt corners or sharp points since it will be appreciated that such regions may attract a relatively high number of charge carriers which in turn may produce a non-uniform electric field.

The generally cylindrical plasma cell 40 may have an outside diameter of 3 to 10 mm and an exit nozzle diameter of 0.5 to 2 mm. The dielectric substrate layers 46, 48 may be 0.1 to 1 mm thick. The electrode strands may be approximately 0.01 mm to 0.1 mm in width and thickness. The protective layer may be approximately 1 mm thick.

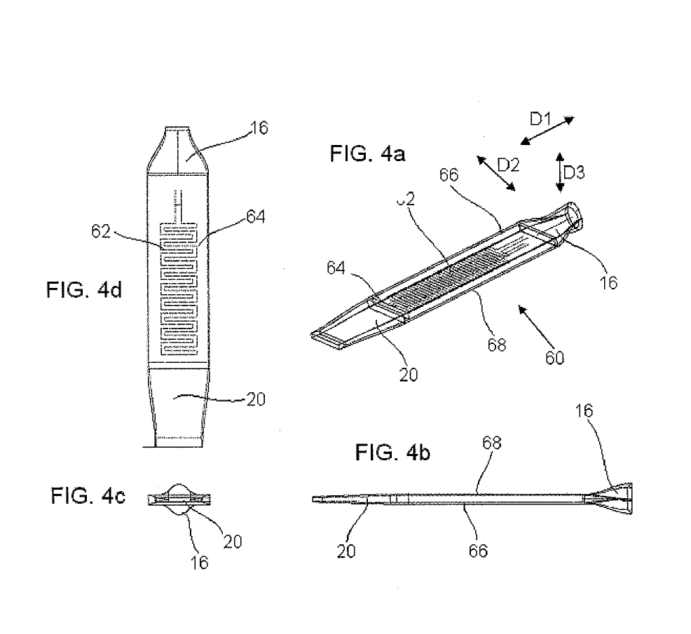

Whilst a generally cylindrical plasma cell is shown in FIG. 3, other shapes may made from the flexible components, for example a cell which conveys gas along a tortuous path. Such an arrangement increases the residence time of gas in the cell and promotes plasma formation. Another plasma cell is shown in FIG. 4 which has a flatter shape.

Referring to FIG. 4, a plasma cell 60 is shown comprising electrodes 62, 64 printed on a dielectric substrate 66. Like reference numerals in FIG. 4 will be used to denote like features discussed above and will not be explained again for brevity. A second dielectric layer 68 covers the electrode pattern, such that the electrode is embedded within the dielectric material. In this example, the dielectric substrate 66 is formed into a generally planar configuration. In this regard, the substrate has a substantially greater extent in a first dimension D1 extending between the inlet 16 and outlet 20 along the flow path and a second dimension D2 generally lateral to the first dimension than in a third dimension D3 generally orthogonal to said first and second dimensions. As shown the first dimension extends generally through the chamber, the second dimension extends across the chamber and the third dimension extends in the thickness of the chamber.

The benefits of the planar cell are threefold. Firstly, the gas is exposed to the electric field for a relatively long period as it passes through the chamber in the first dimension. Secondly, for each unit length in the first dimension, a relatively large amount of gas is exposed to the electric field because of the relatively large width in the second dimension. Thirdly, the relatively small thickness of chamber ensures that the maximum distance of any gas passing through the chamber is only a short distance from the or each electrode, whilst still allowing reasonable gas flow the chamber. It should also be noted that the internal surface area of the plasma chamber is large compared to the volume of gas and therefore is conducive to transporting heat away from the gas. In the example shown in FIG. 1, the width of the chamber is about 10 mm and the length is about 50 mm. The height of the chamber is preferably less than 5 mm and more preferably less than about 2 mm.

In this example, the electrodes are transferred onto each planar side of the substrate 66 in a generally ‘S’ shape configuration. The electrodes cover only a portion of each planar side being spaced from its edges to reduce cross-over of the generated electric field around the edges rather than through the gas chamber in the cell.

The electrode pattern may not be continuous but may alternatively be provided in sections, or discrete patterns, which may be spaced apart one from another. The electrode(s) are preferably configured dependent on the particular characteristics of the cell, for example, the flow rate of gas through the cell, the half life of the active species generated in the cell and the type of treatment required.

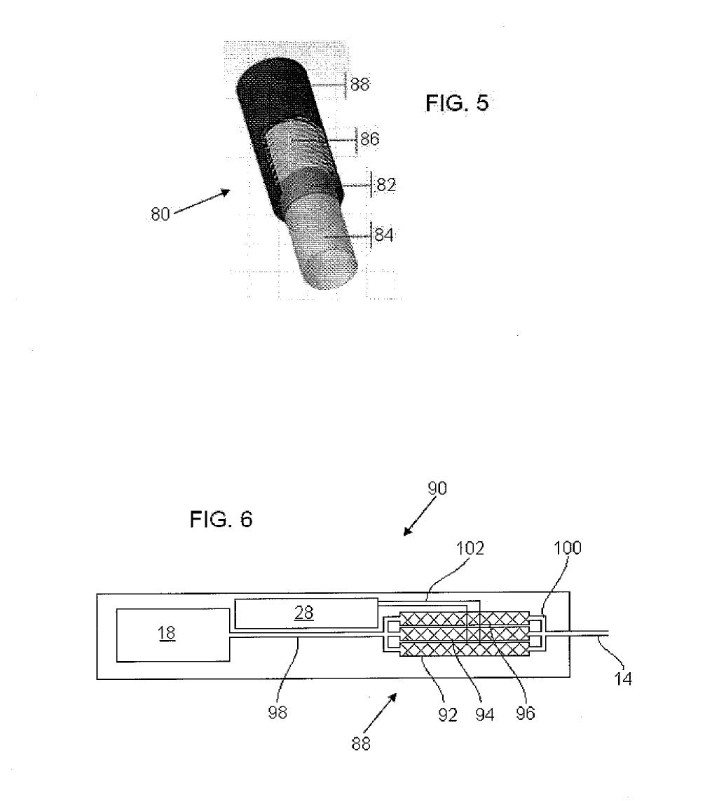

Another embodiment of the invention is shown in FIG. 5. A plasma cell 80 is shown which comprises a generally tubular, or cylindrical, dielectric substrate 82 formed in this case from polyimide. An protective layer 84 which may be made of PTFE covers an inner surface of the dielectric substrate to resist degradation of the substrate during use. An electrode 86 is patterned onto the dielectric substrate. The electrode is made of a fibrous matrix which in this example is steel braid. The electrode pattern is a grid of fibres in this Figure but it will be appreciated that any suitable pattern may be formed. Simple experimentation, involving varying the voltage and frequency, will reveal which pattern performs well and establishes a good electric field in the plasma cell. The electrode pattern may be formed by first transferring a layer of steel, copper or other conductive material to the dielectric substrate and then using a laser to remove material to produce the desired pattern. Alternatively, the fibrous matrix may be transferred to the substrate during the extrusion process. A protective sheath 88 covers the electrode pattern and the dielectric substrate. The sheath provides mechanical support and electrical insulation. Polyimide may be used to form the sheath.

Microlumen® makes suitable tubular structures although for use in the field of medicine where the tubes are used as catheters. The steel braid which is transferred to the polyimide layer provides the tube with structural resilience and is not designed to carry electricity. The polyimide substrate provides a flexible material to allow ending when inserted in the body. It will be appreciated that the size of such tubes are necessarily small (about 1 to 3 mm) to fit inside bodily tracts and such a size also lends itself to use as a plasma cell for the reasons described in detail above.

Referring by way of example to FIG. 2, the plasma cells described herein may be manufactured by patterning an electrode 26 on a dielectric substrate 22, configuring the dielectric substrate, for example into a cylinder, to form a flow path for gas from a cell inlet 16 to a cell outlet 20, and forming an protective lining 32 on an inner surface of the dielectric substrate for resisting reaction of the active species with the dielectric substrate. The order of the steps may be selected as required.

In examples shown in FIGS. 3 and 4, the patterned electrode is deposited on the dielectric substrate by printing techniques known in the manufacture of printed circuit boards. For example, in a subtractive process, a layer of copper may be bonded over the entire substrate, (creating a “blank PCB”) then removing unwanted copper after applying a temporary mask (e.g. by etching), leaving only the desired copper traces. Alternatively, in an additive process, the conductive pathways may be made by depositing traces to the bare substrate (or a substrate with a very thin layer of copper) usually by a complex process of multiple electroplating steps.

The vast majority of circuit boards remain flat in use. However, in a preferred method of manufacturing a plasma cell the dielectric substrate is made from a thin film flexible dielectric material onto which the electrode is patterned. The substrate can then subsequently be shaped to enclose the flow path between the inlet and the outlet, for example as a cylinder, or in a form that that does not follow a straight path between the outlet and the inlet. Alternatively, the circuit can be inserted into a quartz or other dielectric material tube, where it will conform to the shape of the tube. In this way, the plasma cell can be manufactured by the relatively inexpensive printing of conductive tracts on a planar substrate and then formed into the required shape. The protective lining may be formed onto one surface of a planar substrate whilst the electrode pattern is printed on an opposing surface.

Referring to FIG. 5, the patterned electrode is formed of a fibrous matrix which is transferred onto the dielectric substrate either during extrusion of the tubular substrate or subsequent to its manufacture. Since the material selected for the substrate is flexible, the plasma cell can subsequently be formed into any desired shape.

In the present embodiments, the selection of the dielectric material of the substrate should preferably take account of its thermal conductivity and in this regard, polyimide has a relatively good thermal conductivity of around 0.5 W/m.K, so that heat may be conducted away from the gas in the cell. The temperature of the gas mixture discharged from the plasma chamber is preferably less than 60° C., and more preferably less than 40° C.

The electrode(s) may be patterned generally uniformly on the dielectric substrate or may be patterned to produce one region which has a different concentration of conductive tracts than another region. For instance, it may be desirable to produce a stranger electric field towards the outlet of the cell compared towards the inlet of the cell, such that more energy is supplied to the gas as it approaches the treatment region. Alternatively, the electrode pattern may consist of multiple discrete patterns in series spaced apart along the flow path one from another.

The device of the embodiments having the plasma cells described herein lends itself to a compact form and in a preferred arrangement the device is configured to be hand-held and operated, for example, like an electric tooth brush may be hand-held and operated. A hand-held device must be sufficiently small and light that is not unwieldy in use and may be guided relatively precisely for application of generated active species to a treatment region such as a specific tooth in a mouth. In this regard, the device may be configured to have a mass of less than 1 kg, a length of less than 200 mm and a width of 50 mm.

A further device is shown in FIG. 6. Since the plasma cells as described herein may be relatively small (e.g. 50 mm length by 5 mm width), a plasma cell array 88 comprising a plurality of plasma cells may be provided in a single device, which may itself be suitable to be hand-held and operated. In FIG. 6, the device 90 comprises three plasma cells 92, 94, 96 each of which are in flow communication with the source of gas 18 for receiving into the cells gas to be energised and with the nozzle 14 (or each nozzle) for plasma to be delivered from the cells to a treatment region. A gas duct 98 extends from the gas source and trifurcates to deliver gas to each of the cells. Further ducts 100 extend from the cell outlets and converge to deliver active species to the nozzle. The electrode(s) of each cell are connected by electrical conductors 102 to the source of electrical power 28.

The plasma cell array as shown is capable of delivering a greater amount of active species to the treatment region than the single plasma cell of the device shown in FIG. 1. However, unlike a device that simply incorporates a larger plasma cell, the provision of the plasma cell array allows the gas to be in closer proximity to the electrodes of the cells and therefore interact more readily with the electric fields generated. In a larger cell, the maximum distance between the gas and the electrodes is increased and therefore a larger potential would have to be created at the electrode to deliver comparable energy to the gas.

Although in this example, the plasma cell array comprises three plasma cells, any number of cells may be incorporated. Further, the three plasma cells are disposed in parallel relation whereas one or more of the cells may be provided in series, however, a series relationship may be appropriate only if the half life of the active species is sufficiently long that plasma generated in the first of the series survives for application to the treatment region.

1. A device for forming at an ambient atmospheric pressure a gaseous plasma comprising active species for treatment of a treatment region, the device comprising a plasma cell for forming said gaseous plasma for treating the treatment region, the plasma cell comprising an inlet for receiving gas from a source and an outlet for discharging active species generated in the cell, a dielectric substrate made of a polyimide enclosed around a flow path for gas conveyed from the inlet to the outlet and an electrode formed on the dielectric substrate for energising gas along the flow path to form active species, wherein a protective coating made of a dielectric is formed on an inner surface of the dielectric substrate for protecting the dielectric substrate from reaction with the active species.

2. A device according to claim 1, wherein the protective coating is made of a material selected from one of PTFE, FEP or silicone rubber being generally un-reactive with the active species.

3. A device according to claim 1, wherein the electrode is formed by patterning an electrically conductive material on the dielectric substrate.

4. A device according to claim 3, wherein the electrode is printed.

5. A device according to claim 3, wherein the patterned electrode is formed of a fibrous matrix transferred onto the dielectric substrate.

6. A device according to claim 1, wherein the dielectric substrate is flexible and is shaped to define the flow path.

7. A device according to claim 6, wherein the dielectric substrate is formed by a flexible tube enclosing the flow path.

8. A device according to claim 1 further comprising a protective sheath made of a dielectric formed around the dielectric substrate and electrode.

9. A device according to claim 1 wherein a plurality of plasma cells are arranged in a plasma cell array

10. A plasma cell comprising an inlet for receiving gas from a source and an outlet for discharging active species generated in the cell, a dielectric substrate made of a polyimide enclosed around a flow path for gas conveyed from the inlet to the outlet and an electrode formed on the dielectric substrate for energising gas along the flow path to form active species, wherein a protective coating made of a dielectric is formed on an inner surface of the dielectric substrate for protecting the dielectric substrate from reaction with the active species.
